(19) United States
(12) Patent Application Publication
(10) Pub. No.: US 2008/0041435 A1
(43) Pub. Date: Feb. 21, 2008

(54) Diode-based reverse-entropy generator

(76) Inventor: Bret Bernard Cummings, El Segundo, CA (US)

Correspondence Address: Bret Cummings, P.O. Box 485, El Segundo, CA, 90245-0485, US

(21) Appl. No.: 11/499,449

(22) Filed: Aug. 7, 2006

(51) Int. Cl. H01L 35/30; H02N 6/00; H01L 31/042

(52) U.S. Cl. 136/244; 136/205

(57) ABSTRACT

This is an apparatus that converts heat directly into electrical energy by the use of many microscopic alternating layers of electrically-conductive metal and semiconductor diodes. The electron motion that results from microscopic heat gradients and the heat itself causes electrons to irreversibly pass through the diode layers, causing an accumulation of electrical charge. The use of many layers allows the small charge differences between individual layers to mount up, resulting in a substantial voltage.

### CROSS-REFERENCE TO RELATED APPLICATIONS

Not Applicable

### STATEMENT REGARDING FEDERALLY. SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### BACKGROUND OF THE INVENTION

1. Field or Fields of the Invention

electrical physics

2. Background principles

Within an electrically-conductive metal, electrons are highly mobile and can easily flow from atom to atom. Heat gradients produce small electrical currents within metal, and heat itself causes electron motion. A diode is a one-way pathway of electrical flow. A diode is composed of 2 layers of semiconductors, with metal contacts that each touch only 1 of the 2 layers. One of the semiconductor layers is naturally positively-charged, whereas the other layer is naturally negatively-charged. Electrons can only flow from the negatively-charged semiconductor layer to the positively-charged semiconductor layer, and thus can only flow from one electrical contact to the other, unless the voltage in the reverse direction is very strong.

3. Comparison to Prior Art

There has previously not been any method by which to extract energy from heat itself, though extraction of energy from the physical expansion that heat produces (often by water boiling), as distinguished from heat itself, is perhaps the most common method of generating electrical and mechanical energy. This invention also serves the purpose of cooling. For that purpose, ventilation holes, fans, thermal-conductive metal heat sinks, and reflective surfaces are typically used.

### BRIEF SUMMARY OF THE INVENTION

This is an apparatus that converts heat directly into electrical energy by the use of many microscopic alternating layers of electrically-conductive metal and semiconductor diodes. The electron motion that results from microscopic heat gradients and the heat itself causes electrons to irreversibly pass through the diode layers, causing an accumulation of electrical charge. The use of many layers allows the small charge differences between individual layers to mount up, resulting in a substantial voltage.

### BRIEF DESCRIPTION OF THE DRAWING OR DRAWINGS

Not Applicable

### DETAILED DESCRIPTION OF THE INVENTION

### Application:

This invention serves 2 general purposes, which are energy generation and cooling. These generators can be used in electrical appliances that are prone to high heat, particularly computers, in which the energy created can be used to contribute to the power of the appliance itself. They can be used in vehicle engines to prevent overheating and to increase mileage when driving at high speeds, as high heat decreases mileage. In vehicle engines, the power of the generator can be used to charge the battery. They would be especially useful for automobile hybrid engines, which rely heavily on electrical power. They can be used to cool hot homes and other buildings while simultaneously providing power to the conventional air conditioning and/or other electrical devices. They can be used to control excess heat at power plants while simultaneously contributing to power output. They can be used in spacecraft, in which heat dispersal is otherwise difficult.

### Description of the Composition and Function of the Invention:

This invention is composed of microscopic alternating layers of conductive and semiconductive substances. The conductive and semiconductive substances preferably each have high electron mobility, as high electron mobility is essential for this generator to work, due to the initial voltage produced by heat being very low. Gallium arsenide is the preferable semiconductor. The conductive material may be silver, copper, gold, or aluminum, though silver and especially gold are impractical because of their rarity. The generator preferably incorporates an intermediate substance between the positions of the conductor and the semiconductor, that is composed of a substance that is intermediate between that of the conductor and the semiconductor, such as aluminum gallium arsenide, so as to further increase electron mobility. In the case of an aluminum conductor, the sequence of layers would go: aluminum, negative aluminum gallium arsenide, negative gallium arsenide, positive gallium arsenide, positive aluminum gallium arsenide. The layers must be very thin, else they will not effectively pass charge through the diode layers, due to the electron movements being naturally dispersed through the conductor. The thicker the layers are, the less charge they will pass. The layers should be as thin as is possible without disrupting the function of the conductors or semiconductors. The layers should not be thicker than 10 micrometers. Because electrically conductive metals are also effective conductors of heat, the heat that is converted into electricity will be rapidly replaced.

It may also be beneficial to have the conductor layers consist not of a single contiguous plane, but of a lattice of adjacent square or hexagonal areas that are separated by a different substance, either an insulator or semiconductor from the above and below layers. The purpose of that lattice separation would be to prevent the dispersion of mobile electrons to the surrounding areas of the conductor rather than across the diodes.

The generator has many complete sequences of layers, each of which may itself simply be called a ‘layer’. The width of the layers are tapered down to a wire on the positive and negative ends. Increasing the surface area of the layers with the highest surface area increases the current. The layers are not necessarily flat, but may be convoluted so as to create more surface area for the largest layers. Increasing the quantity of layers, resulting in greater thickness, does not increase the current (amps) of the layers, but does increase the strength of the pull (volts). That is because there can only be a small charge difference between multiple conductive layers, because the charge difference is caused only by diodes sorting out the random electron motion of heat. The use of a very large number of layers thus allows the charge to be gradually ramped up from the middle of the generator to the 2 wire terminals, allowing for a substantial voltage.

The outer surface of the generator is covered with a thin layer of insulation, such as plastic, so as to prevent any charge from being externally transferred between different conducting layers, which would cause the generator to cease functioning.

### Method of Manufacture:

These generators are manufactured layer by layer, in which the layers are either flat or convoluted. The successive layers are deposited by one or more of the usual methods of depositing substances in layers with a thickness in the range of micrometers or nanometers. Those methods include chemical vapor deposition, epitaxy, physical vapor deposition, and casting (applying material dissolved in temporary solvent).

I claim the following as my invention:

1. any apparatus that produces electricity from heat, that is composed of many very thin alternating layers of electrically-conductive metal and semiconductor that serves as diodes.
